(19) United States
(12) Patent Application Publication
(10) Pub. No.: US 2025/0006813 A1
(43) Pub. Date: Jan. 2, 2025

(54) TRANSISTOR AND METHOD OF MANUFACTURING TRANSISTOR

(71) Applicant: INSTITUTE OF MICROELECTRONICS, CHINESE ACADEMY OF SCIENCES, Beijing (CN)

(72) Inventors: Yongliang LI, Beijing (CN); Fei ZHAO, Beijing (CN)

(21) Appl. No.: 18/754,572

(22) Filed: Jun. 26, 2024

(30) Foreign Application Priority Data
Jun. 27, 2023 (CN) 202310769088.2

(51) Int. Cl. H01L 29/423; H01L 21/8234; H01L 27/088; H01L 29/06; H01L 29/66; H01L 29/775; H01L 29/786

(52) U.S. Cl. CPC H01L 29/42392; H01L 21/823412; H01L 21/823418; H01L 21/823437; H01L 27/088; H01L 29/0673; H01L 29/66439; H01L 29/66545; H01L 29/775; H01L 29/78696

(57) ABSTRACT

A transistor and a manufacturing method. The transistor includes a semiconductor base substrate, an active structure, a dielectric structure, and a gate stack structure. The active structure is formed on the semiconductor base substrate. The active structure includes a source region, a drain region, and a channel region located between the source region and the drain region. The channel region includes at least two nanostructures stacked in a thickness direction of the semiconductor base substrate. In the channel region, a bottom nanostructure has a greater width than other nanostructures. The dielectric structure is formed between the semiconductor base substrate and the active structure. The dielectric structure is in contact with the bottom nanostructure. The gate stack structure is formed on a surface of the bottom nanostructure not in contact with the dielectric structure, and the gate stack surrounds a periphery of the other nanostructures.

### CROSS REFERENCE TO RELATED APPLICATION

This application claims priority to Chinese Patent Application No. 202310769088.2, filed on Jun. 27, 2023, the entire content of which is incorporated herein in its entirety by reference.

### TECHNICAL FIELD

The present disclosure relates to the field of semiconductor technology, and in particular to a transistor and a method of manufacturing a transistor.

### BACKGROUND

Compared with planar transistors, fin field effect transistors and gate-all-around transistors have stronger gating capabilities and may suppress short channel effects.

However, it is difficult for existing manufacturing methods to ensure a high conduction uniformity between different layers of nanostructures included in a channel region of a transistor while suppressing a parasitic channel leakage in the transistor, which is not conducive to improving an electrical performance of the transistor.

### SUMMARY

In a first aspect, the present disclosure provides a transistor, which includes a semiconductor base substrate, an active structure, a dielectric structure, and a gate stack structure. The active structure is formed on the semiconductor base substrate. The active structure includes a source region, a drain region, and a channel region located between the source region and the drain region. The channel region includes at least two nanostructures stacked in a thickness direction of the semiconductor base substrate. In the channel region, a bottom nanostructure of the at least two nanostructures has a greater width than others of the at least two nanostructures. The dielectric structure is formed between the semiconductor base substrate and the active structure, and the dielectric structure is in contact with the bottom nanostructure. The gate stack structure is formed on a surface of the bottom nanostructure not in contact with the dielectric structure, and the gate stack structure surrounds a periphery of the others of the at least two nanostructures.

In a second aspect, the present disclosure further provides a method of manufacturing a transistor, which includes: firstly providing a semiconductor base substrate; then forming a dielectric structure and an active structure on the semiconductor base substrate, where the active structure includes a source region, a drain region, and a channel region located between the source region and the drain region; the channel region includes at least two nanostructures stacked in a thickness direction of the semiconductor base substrate; in the channel region, a bottom nanostructure of the at least two nanostructures has a greater width than others of the at least two nanostructures; the dielectric structure is formed between the semiconductor base substrate and the active structure and is in contact with the bottom nanostructure; and then forming a gate stack structure, where the gate stack structure is formed on a surface of the bottom nanostructure not in contact with the dielectric structure, and the gate stack structure surrounds a periphery of the others of the at least two nanostructures.

### BRIEF DESCRIPTION OF THE DRAWINGS

The accompanying drawings described herein are used to help further understanding of the present disclosure and constitute a part of the present disclosure. The exemplary embodiments of the present disclosure and the descriptions thereof are used to explain the present disclosure and do not constitute improper limitations on the present disclosure. In the accompanying drawings:

FIG. 1 shows a first schematic structural diagram of a transistor during a manufacturing process according to embodiments of the present disclosure;

FIG. 2 shows a second schematic structural diagram of a transistor during a manufacturing process according to embodiments of the present disclosure;

FIG. 3 shows a third schematic structural diagram of a transistor during a manufacturing process according to embodiments of the present disclosure;

FIG. 4 shows a fourth schematic structural diagram of a transistor during a manufacturing process according to embodiments of the present disclosure;

FIG. 5 shows a fifth schematic structural diagram of a transistor during a manufacturing process according to embodiments of the present disclosure;

FIG. 6 shows a sixth schematic structural diagram of a transistor during a manufacturing process according to embodiments of the present disclosure;

FIG. 7 shows a seventh schematic structural diagram of a transistor during a manufacturing process according to embodiments of the present disclosure;

Part (1) and Part (2) in FIG. 8 respectively show an eighth schematic structural diagram and a ninth schematic structural diagram of a transistor during a manufacturing process according to embodiments of the present disclosure;

Part (1) and Part (2) in FIG. 9 respectively show a tenth schematic structural diagram and an eleventh schematic structural diagram of a transistor during a manufacturing process according to embodiments of the present disclosure;

Part (1) and Part (2) in FIG. 10 respectively show a twelfth schematic structural diagram and a thirteenth schematic structural diagram of a transistor during a manufacturing process according to embodiments of the present disclosure;

Part (1) and Part (2) in FIG. 11 respectively show a fourteenth schematic structural diagram and a fifteenth schematic structural diagram of a transistor during a manufacturing process according to embodiments of the present disclosure;

Part (1) and Part (2) in FIG. 12 respectively show a sixteenth schematic structural diagram and a seventeenth schematic structural diagram of a transistor during a manufacturing process according to embodiments of the present disclosure;

Part (1) and Part (2) in FIG. 13 respectively show an eighteenth schematic structural diagram and a nineteenth schematic structural diagram of a transistor during a manufacturing process according to embodiments of the present disclosure;

Part (1) and Part (2) in FIG. 14 respectively show a twentieth schematic structural diagram and a twenty-first schematic structural diagram of a transistor during a manufacturing process according to embodiments of the present disclosure;

Part (1) and Part (2) in FIG. 15 respectively show a twenty-second schematic structural diagram and a twenty-third schematic structural diagram of a transistor during a manufacturing process according to embodiments of the present disclosure;

FIG. 16 shows a twenty-fourth schematic structural diagram of a transistor during a manufacturing process according to embodiments of the present disclosure;

FIG. 17 shows a twenty-fifth schematic structural diagram of a transistor during a manufacturing process according to embodiments of the present disclosure;

FIG. 18 shows a twenty-sixth schematic structural diagram of a transistor during a manufacturing process according to embodiments of the present disclosure;

FIG. 19 shows a twenty-seventh schematic structural diagram of a transistor during a manufacturing process according to embodiments of the present disclosure;

FIG. 20 shows a twenty-eighth schematic structural diagram of a transistor during a manufacturing process according to embodiments of the present disclosure;

FIG. 21 shows a twenty-ninth schematic structural diagram of a transistor during a manufacturing process according to embodiments of the present disclosure;

Part (1) and Part (2) in FIG. 22 respectively show a thirtieth schematic structural diagram and a thirty-first schematic structural diagram of a transistor during a manufacturing process according to embodiments of the present disclosure.

Reference numerals: 11—semiconductor base substrate, 12—layer to be oxidized, 13—channel layer, 14—sacrificial layer, 15—third fin structure, 16—third protective layer, 17—first fin structure, 18—first protective layer, 19—second protective layer, 20—dielectric structure, 21—shallow trench isolation structure, 22—second fin structure, 23—sacrificial gate, 24—gate spacer, 25—semiconductor structure, 26—source region, 27—drain region, 28—interlayer dielectric layer, 29—channel region, 30—nanostructure, 31—gate stack structure.

### DETAILED DESCRIPTION OF EMBODIMENTS

Embodiments of the present disclosure will be described below with reference to the accompanying drawings. However, it should be understood that these descriptions are just exemplary and are not intended to limit the scope of the present disclosure. In addition, in the following explanations, descriptions of well-known structures and technologies are omitted to avoid unnecessarily obscuring the concepts of the present disclosure.

Various schematic structural diagrams according to embodiments of the present disclosure are shown in the accompanying drawings. These diagrams are not drawn to scale, in which some details are enlarged and some details may be omitted for clarity of presentation. Shapes of various regions and layers as well as relative sizes and positional relationships thereof shown in the diagrams are just exemplary. In practice, there may be deviations due to manufacturing tolerances or technical limitations, and those skilled in the art may additionally design regions/layers with different shapes, sizes and relative positions according to actual needs.

In the context of the present disclosure, when a layer/element is referred to as being located “on” a further layer/element, that layer/element may be located directly on the further layer/element, or there may be an intermediate layer/element between them. In addition, if a layer/element is located “on” a further layer/element in an orientation, the layer/element may be located “below” the further layer/element when the orientation is reversed. In order to make the technical problems to be solved, the technical solutions and the beneficial effects of the present disclosure more clearly understood, the present disclosure will be further described in detail below in conjunction with the accompanying drawings and embodiments. It should be understood that the specific embodiments described herein are just used to explain the present disclosure rather than limit the present disclosure.

In addition, the terms “first”, “second”, etc. are used for descriptive purposes only and should not be construed as indicating or implying relative importance or implying the number of technical features indicated. Therefore, a feature defined by “first” or “second” may explicitly or implicitly include one or more features. In the description of the present disclosure, “a plurality” means two or more, unless otherwise clearly defined. “Several” means one or more, unless otherwise clearly defined.

In the descriptions of the present disclosure, it should be noted that, unless otherwise specified and defined, the terms “installation”, “interconnection” and “connection” should be construed broadly. For example, those terms may refer to a fixed connection, a detachable connection, or an integrated connection, may refer to a mechanical connection or an electrical connection, may refer to a direct connection or an indirect connection through an intermediate medium, and may refer to an internal connection of two elements or an interaction relationship between two elements. For those ordinary skilled in the art, the specific meanings of the above terms in the present disclosure may be understood according to specific cases.

Compared with planar transistors, fin field effect transistors and gate-all-around transistors have stronger gating capabilities and may suppress short channel effects, so that fin field effect transistors and gate-all-around transistors have higher operating performance.

For a gate-all-around transistor, there is a problem of parasitic channel leakage during an actual operation. To address this problem, those skilled in the art generally make improvements by two methods. A first method is to use a semiconductor base substrate having a buried oxide layer, such as a silicon-on-insulator substrate, and the parasitic channel leakage may be prevented by the buried oxide layer because the buried oxide layer is a non-conductive insulating layer. A second method is to use an anti-punch-through implantation process to suppress the parasitic channel leakage. Specifically, during a process of manufacturing a gate-all-around transistor, after a fin structure and a shallow trench isolation structure are formed on the substrate, impurity ions of a conductivity type opposite to that of impurities doped in the source region and the drain region are injected into at least the fin structure through the anti-punch-through implantation process to form a barrier layer in middle and lower parts of the fin structure, so that a parasitic channel leakage may be suppressed by the highly doped barrier layer.

Secondly, when a gate-all-around transistor, which is manufactured by existing manufacturing methods, includes a channel region having multiple layers of nanostructures spaced in a thickness direction of the semiconductor base substrate, the gate-all-around transistor may have a poor driving performance. Specifically, in the gate-all-around transistor, a source electrode electrically connected to the source region is formed on a top of the source region, and a drain electrode electrically connected to the drain region is formed on a top of the drain region. Therefore, in the thickness direction towards the semiconductor base substrate, a distance between each nanostructure and the source electrode and a distance between each nanostructure and the drain electrode are greater than a distance between a further nanostructure above that nanostructure and the source electrode and a distance between the further nanostructure and the drain electrode, respectively. Accordingly, when the gate-all-around transistor is in an on state, the source electrode and the drain electrode have a short transmission path through an upper nanostructure and have a longer transmission path through a lower nanostructure. As the transmission path is proportional to an on-resistance, each nanostructure may have a greater on-resistance than an upper nanostructure. Under the influence of on-resistance, there is a poor conduction uniformity between different layers of nanostructures, which in turn leads to a poor driving performance of the gate-all-around transistor.

In summary, it is difficult for existing manufacturing methods to ensure a high conduction uniformity between different layers of nanostructures included in a channel region of a manufactured transistor while suppressing a parasitic channel leakage in the transistor, which is not conducive to improving the electrical performance of the transistor.

An objective of the present disclosure is to provide a transistor and a method of manufacturing a transistor, which are used to improve a conduction uniformity between different nanostructures included in a channel region while suppressing a parasitic channel leakage, thereby improving an electrical performance of the transistor.

The embodiments of the present disclosure provide a transistor and a method of manufacturing a transistor. In the transistor provided by the embodiments of the present disclosure, a dielectric structure is formed between the semiconductor base substrate and the active structure to prevent a parasitic channel leakage and a source-drain leakage. Furthermore, the bottom nanostructure in the channel region is in contact with the dielectric structure and has a width greater than a width of the other nanostructures, so that the bottom nanostructure has a high conduction uniformity with the other nanostructures, which may improve the driving performance of the transistor.

As shown in FIG. 21 as well as Part (1) and Part (2) of FIG. 22, in a first aspect, the transistor provided by the embodiments of the present disclosure includes: a semiconductor base substrate 11, an active structure, a dielectric structure 20, and a gate stack structure 31. The active structure is formed on the semiconductor base substrate 11. The active structure includes a source region 26, a drain region 27, and a channel region 29 located between the source region 26 and the drain region 27. In a thickness direction of the semiconductor base substrate 11, the channel region 29 includes at least two nanostructures 30 stacked. In the channel region 29, a bottom nanostructure 30 of the at least two nanostructures has a greater width than others nanostructures 30. The dielectric structure 20 is formed between the semiconductor base substrate 11 and the active structure. The dielectric structure 20 is in contact with the bottom nanostructure 30. The gate stack structure 31 is formed on a surface of the bottom nanostructure 30 not in contact with the dielectric structure 20, and the gate stack structure 31 surrounds a periphery of the other nanostructures 30.

Specifically, the semiconductor base substrate may be a semiconductor substrate made of any semiconductor material such as a silicon substrate, a germanium silicon substrate, etc., and may have a low manufacturing cost. The semiconductor base substrate may have an active region and an isolation region. A scope of the active region and the isolation region may be determined according to actual application scenarios and is not specifically limited here.

For the above-mentioned dielectric structure, the dielectric structure may be made of an insulating material such as silicon oxide or germanium oxide. Based on this, as shown in FIG. 21, the dielectric structure 20 is formed between the semiconductor base substrate 11 and the active structure. In this case, the dielectric structure 20 may isolate the source region 26, the drain region 27 and the channel region 29 included in the active structure from the semiconductor base substrate 11. Since the dielectric structure 20 is a non-conductive insulating structure, when the gate stack structure 31 is loaded with an appropriate voltage, an existence of the dielectric structure 20 may allow the source region 26 and the drain region 27 to conduct only through the channel region 29 and allow the source region 26 and the drain region 27 not to conduct with the semiconductor base substrate 11 located below the dielectric structure 20, so that problems of a parasitic channel leakage and a source-drain leakage may be solved. Furthermore, since the dielectric structure 20 is a film layer subsequently formed on the semiconductor base substrate 11 and is not a part of the semiconductor base substrate 11, a silicon substrate, a germanium silicon substrate or other semiconductor base substrates 11 that meet the requirements and have a lower cost than a silicon-on-insulator substrate may be used during a process of manufacturing the transistor, so as to reduce a manufacturing cost of the transistor while solving the problems of parasitic channel leakage and source-drain leakage. Moreover, the problems of parasitic channel leakage and source-drain leakage are solved by insulation properties of the dielectric structure 20, and there is no need to use an anti-punch-through implantation process to treat the fin structure of the transistor, so that a reduction of carrier migration rate in the channel region 29, a damage caused by high-speed ions to the fin structure and other problems caused by the implantation process may be prevented, which may help improve an operating performance of the transistor.

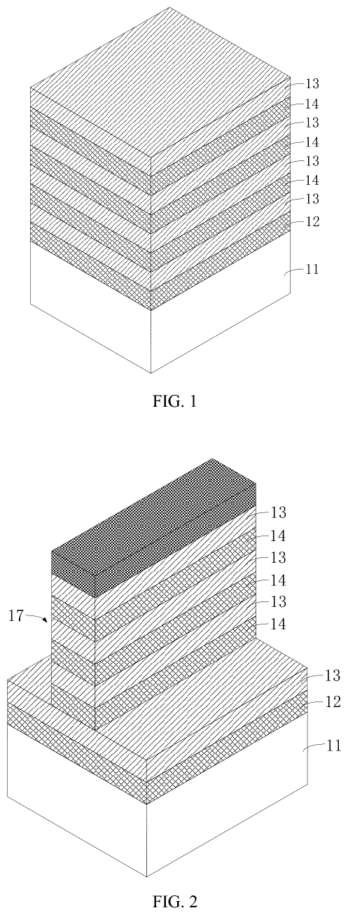

In actual applications, the dielectric structure is formed on the active region of the semiconductor base substrate. In addition, as shown in FIG. 1 to FIG. 21, the dielectric structure 20 may be obtained by performing a selective oxidation on the layer to be oxidized 12 that is formed on the semiconductor base substrate 11 and has been patterned. Moreover, the layer to be oxidized 12 is made of the same material as the sacrificial layer 14. Therefore, in this case, the material of the dielectric structure 20 is an oxide of the material of the sacrificial layer 14.

A thickness of the dielectric structure may be determined according to the actual application scenario and is not specifically limited here. Secondly, a width of the dielectric structure (a width direction of the dielectric structure is parallel to a width direction of the gate stack structure) may be equal to the width of the bottom nanostructure. Alternatively, as shown in Part (1) and Part (2) in FIG. 22, the width of the dielectric structure 20 may be less than the width of the bottom nanostructure 30. Specifically, during the actual manufacturing process, when both the layer to be oxidized used to manufacture the dielectric structure 20 and the sacrificial layer are made of germanium silicon or germanium, and the channel region 29 and the semiconductor base substrate 11 are made of silicon, as shown in Parts (1) and Parts (2) in FIG. 9 to FIG. 13, during a process of etching the bottom channel layer 13, the layer to be oxidized 12 and a part of the semiconductor base substrate 11, an etchant for etching the channel layer 13 and the semiconductor base substrate 11 may also affect the layer to be oxidized 12, so that the width of the layer to be oxidized 12 after patterning is less than the width of the bottom channel layer 13, and thus the width of the dielectric structure is less than the width of the bottom nanostructure. If an etchant with a higher selectivity is used, it is advantageous to make the width of the dielectric structure be equal to the width of the bottom nanostructure.

For the above-mentioned active structure, the source region and the drain region included in the active structure may be directly formed on the dielectric structure. Alternatively, as shown in FIG. 21, the transistor provided in the embodiments of the present disclosure further includes a semiconductor structure 25 integrally formed with the bottom nanostructure 30. The semiconductor structure 25 is located between the source region 26 and the dielectric structure 20 as well as between the drain region 27 and the dielectric structure 20. In other words, the source region 26 and the drain region 27 are formed on the semiconductor structure 25. In this case, as shown in FIG. 17 and FIG. 18, when the transistor includes the above-mentioned semiconductor structure 25 and the source region 26 and the drain region 27 are formed by source-drain epitaxy, after a part of the second fin structure located above the bottom channel layer 13 is removed, it is possible to not only use at least a remaining part of the channel layer 13 as a seed layer for growing the source region 26 and the drain region 27, but also use the semiconductor structure 25 as a seed layer for growing the source region 26 and the drain region 27, so that defects in the source region 26 and the drain region 27 may be reduced, and a yield of the transistor may be improved. A material and a specification of the semiconductor structure 25 may be determined according to the material and specification of the channel region, which are not specifically limited here.

The source region and the drain region may be made of any semiconductor material such as silicon, silicon germanium, or germanium. The material of the source region may be the same as or different from the material of the drain region. For example, both the material of the source region and the material of the drain region may be silicon, silicon germanium, or germanium. For another example, the material of the source region may be silicon, and the material of the drain region may be silicon germanium.

The channel region in the active structure includes at least two nanostructures. As shown in FIG. 21 as well as Part (1) and Part (2) of FIG. 22, the bottom nanostructure 30 is in contact with the dielectric structure 20, and the other nanostructures 30 included in the channel region 29 are distributed at intervals above the bottom nanostructure 30 in the thickness direction of the semiconductor base substrate 11. In this case, the gate stack structure 31 is formed on a surface of the bottom nanostructure 30 not in contact with the dielectric structure 20, and the gate stack structure 31 surrounds a periphery of the other nanostructures 30. Accordingly, the gate stack structure 31 and the bottom nanostructure 30 form a FinFET-like architecture, while the gate stack structure 31 and the other nanostructures 30 form a gate-all-around architecture. Therefore, in a case that the channel region 29 includes a plurality of layers of nanostructures 30, it is possible to not only improve a structural reliability of the channel region 29 by a direct contact between the bottom nanostructure 30 and the dielectric structure 20, but also improve a control ability of the gate stack structure 31 of the transistor over the channel region 29 and suppress a short channel effect through the gate-all-around architecture formed by the gate stack structure 31 and the other nanostructures 30, thereby further improving the electrical performance of the transistor.

Specifically, a specific number of layers of nanostructures included in the channel region may be determined according to actual needs and is not specifically limited here. As for the specification of the nanostructures included in the channel region, as shown in Part (1) and Part (2) in FIG. 22, the bottom nanostructure 30 has a greater width than the other nanostructures 30. In this case, when other factors are the same, the bottom nanostructure 30 has a greater conduction area than the other nanostructures 30. In the direction towards the semiconductor base substrate 11, a voltage applied to both ends of the nanostructure 30 in an upper layer in a length direction is greater than a voltage applied to both ends of the bottom nanostructure 30 in a length direction. However, when the conduction area of the bottom nanostructure 30 is increased, a conduction current of the bottom nanostructure 30 may also be increased, which may help obtain a high conduction uniformity between the bottom nanostructure 30 and the other nanostructures 30, thereby improving a driving performance of the transistor.

As shown in Part (2) of FIG. 22, in the channel region 29, the other nanostructures 30 other than the bottom nanostructure 30 have the same width. In this case, as shown in FIG. 2, a first fin structure 17 used to manufacture the other nanostructures 30 may be obtained by patterning only once, so that a manufacturing difficulty of the channel region may be reduced, and a manufacturing process of the channel region may be simplified. Alternatively, as shown in Part (1) of FIG. 22, the widths of different layers of nanostructures 30 included in the channel region 29 gradually increase in the direction towards the semiconductor base substrate 11. This is beneficial to gradually increase the conduction areas of different layers of nanostructures 30 included in the channel region 29 in the direction towards the semiconductor base substrate 11, which may help the nanostructures 30 at different heights to have equal conduction currents, thereby further improving the conduction uniformity between different nanostructures 30.

In the actual application, as shown in Part (1) and Part (2) of FIG. 22, central axes of different nanostructures 30 included in the channel region 29 may coincide with each other. In this case, both sidewalls of each nanostructure 30 above the bottom nanostructure 30 in the length direction are recessed inward by the same length relative to both sidewalls of the bottom nanostructure 30 in the length direction. Alternatively, the central axes of different nanostructures included in the channel region may be parallel to but not coincide with each other. In this case, in the actual manufacturing process, during a process of patterning the channel layer used to manufacture the nanostructure, if other structures located on both sides of the channel layer in the length direction have different distances from the channel layer, the etchant may etch the channel layer to different degrees on both sides of the channel layer in the length direction, and thus the central axes of the nanostructures 30 formed based on different channel layers do not coincide.

In addition, as shown in FIG. 21, different nanostructures 30 may have the same height. Alternatively, the height of the bottom nanostructure may be greater than the height of the other nanostructures. In this case, it may be that only the height of the bottom nanostructure is greater than the height of the other nanostructures, and the other nanostructures have the same height. Alternatively, it may be that the heights of different nanostructures gradually increase in the thickness direction towards the semiconductor base substrate, which may help increase the conduction area of the bottom nanostructure, then help the nanostructures at different heights to have equal conduction currents, thereby further improving the conduction uniformity between different nanostructures.

The specific widths and heights of different nanostructures included in the channel region may be determined according to a height at which each nanostructure is located and the actual application scenario, which are not specifically limited here. In addition, the channel region may be made of silicon, silicon germanium, or Group III-V semiconductor materials. For example, the channel region may be made of silicon.

For the above-mentioned gate stack structure, as shown in FIG. 21 as well as Part (1) and Part (2) of FIG. 22, the gate stack may include a gate dielectric layer and a gate electrode that are formed at least on a periphery of each nanostructure 30 through a gap. The gate dielectric layer may be further formed above a part of the semiconductor base substrate 11 that exposes a gate formation region. Specifically, the gate dielectric layer may be made of an insulating material having a low dielectric constant such as silicon oxide or silicon nitride, or an insulating material having a high dielectric constant such as HfO₂, ZrO₂, TiO₂ or Al₂O₃. The gate electrode may be made of a conductive material such as doped polysilicon, TiN, TaN or TiSiN. A thickness of the gate dielectric layer and a thickness of the gate electrode may be set according to actual needs and are not specifically limited here.

In some cases, as shown in FIG. 21 as well as Part (1) and Part (2) of FIG. 22, the transistor provided by the embodiments of the present disclosure may further include a shallow trench isolation structure 21, a gate spacer 24, and an interlayer dielectric layer 28. The shallow trench isolation structure 21 is formed at least on an isolation region of the semiconductor base substrate 11. The shallow trench isolation structure 21 and the dielectric structure 20 are not integrally formed, and a top height of the shallow trench isolation structure 21 may be any height less than or equal to a top height of the dielectric structure 20, as long as it may be applied to the transistor provided by the embodiments of the present disclosure. In addition, the shallow trench isolation structure 21 may be made of an insulating material such as SiN, Si₃N₄, SiO₂ or SiCO. It should be understood that when other transistors or conductive structures are further formed on the semiconductor base substrate 11, the shallow trench isolation structure 21 formed on the isolation region of the semiconductor base substrate 11 may isolate the transistor provided by the embodiments of the present disclosure from the source region 26 or the drain region 27 of other transistors and from other conductive structures, so as to avoid electrical connection with each other and improve a reliability between the transistor and other structures formed on the semiconductor base substrate 11. In addition, the interlayer dielectric layer 28 covers the semiconductor base substrate 11, and a top of the interlayer dielectric layer 28 is flush with a top of the gate stack structure 31. It should be understood that during the process of manufacturing the transistor provided by the embodiments of the present disclosure, as shown in FIG. 20, an existence of the interlayer dielectric layer 28 may protect the source region 26 and the drain region 27 from being affected by etching, cleaning and other operations when the sacrificial gate and the sacrificial layer are etched. Specifically, the interlayer dielectric layer 28 may be made of an insulating material such as SiO₂ or SiN. For the above-mentioned gate spacer 24, as shown in FIG. 21, the gate spacer 24 is formed between the interlayer dielectric layer 28 and the gate stack structure 31. An existence of the gate spacer 24 facilitates the formation of the gate stack structure 31 of the transistor and the isolation of the gate stack structure 31 from a subsequently formed conductive structure. The gate spacer 24 is made of an insulating material. Specifically, the material of the gate spacer 24 and the thickness of the gate spacer 24 may be designed according to actual application scenarios and are not specifically limited here.

In a second aspect, the embodiments of the present disclosure provide a method of manufacturing a transistor. The manufacturing process will be described below according to the perspective views or cross-sectional views for operations shown in FIG. 1 to FIG. 22. Specifically, the method of manufacturing the transistor includes the following steps.

Firstly, a semiconductor base substrate is provided. A specific structure of the semiconductor base substrate may refer to the above and will not be described in detail here.

Then, as shown in FIG. 20, a dielectric structure 20 and an active structure are formed on the semiconductor base substrate 11. The active structure includes a source region 26, a drain region 27, and a channel region 29 located between the source region 26 and the drain region 27. In a thickness direction of the semiconductor base substrate 11, the channel region 29 includes at least two nanostructures 30 stacked. In the channel region 29, a width of the bottom nanostructure 30 is greater than a width of the other nanostructures 30. The dielectric structure 20 is formed between the semiconductor base substrate 11 and the active structure, and is in contact with the bottom nanostructure 30.

During an actual manufacturing process, a layer to be oxidized used to manufacture the dielectric structure may be formed on the semiconductor base substrate before a formation of a channel layer and a sacrificial layer used to manufacture the active structure. Based on this, after corresponding patterning is performed, the dielectric structure may be formed by performing a selective oxidation on the layer to be oxidized. The material of the layer to be oxidized may be the same as that of the sacrificial layer. Accordingly, the formation of the channel layer, the sacrificial layer and the layer to be oxidized only needs two different semiconductor materials, so that a difficulty of subsequent selective treatment may be reduced. Certainly, the material of the layer to be oxidized may also be different from the material of the sacrificial layer.

The dielectric structure may be formed by two methods according to whether a corresponding protective layer is provided to protect the bottom channel layer when a selective oxidation is performed on the layer to be oxidized that has been patterned.

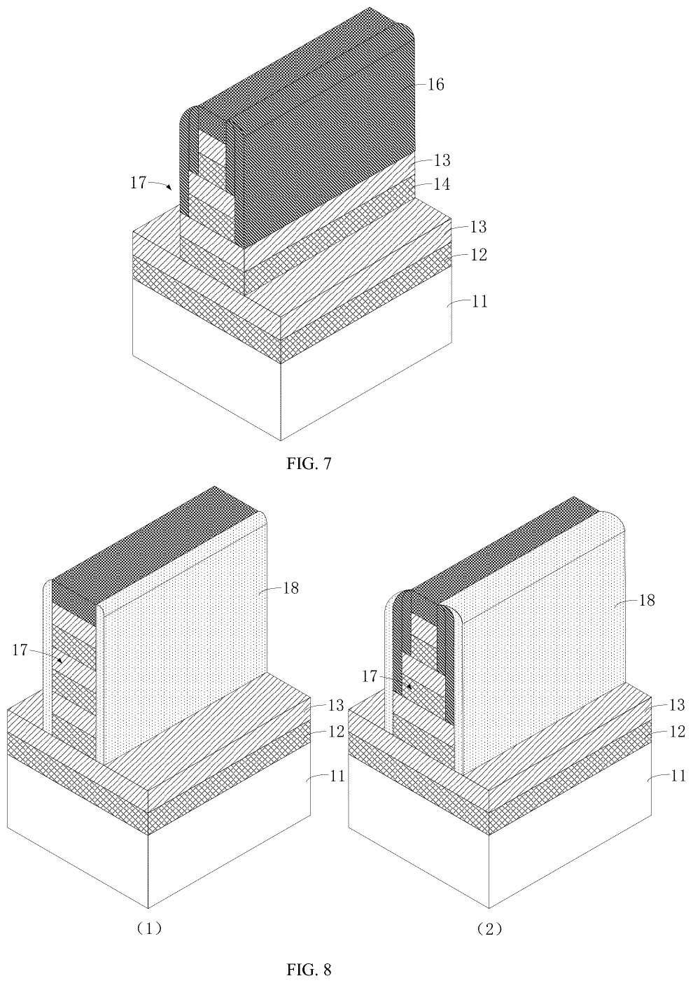

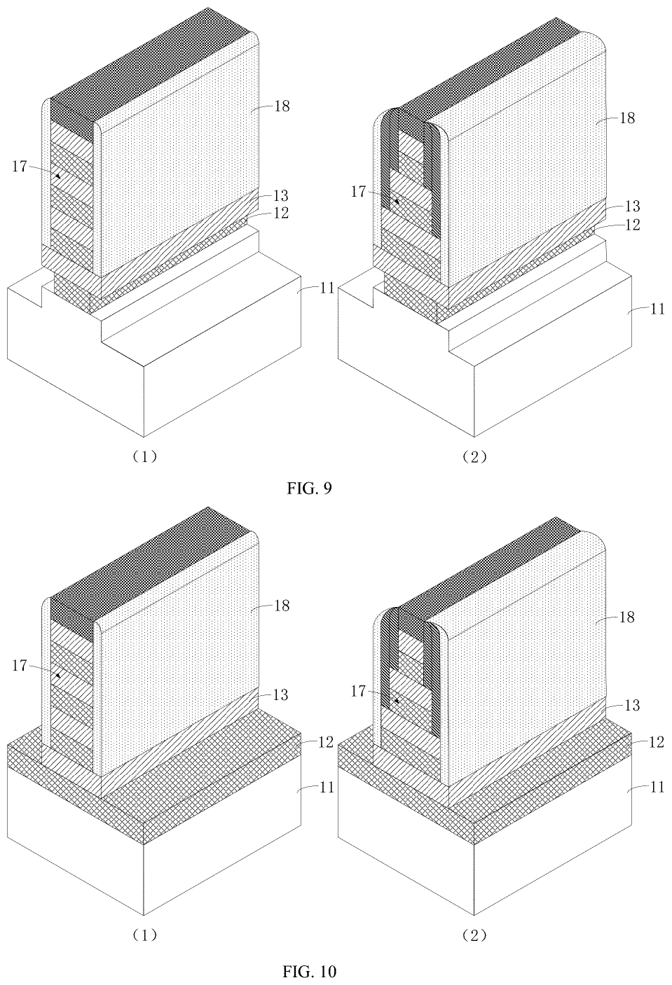

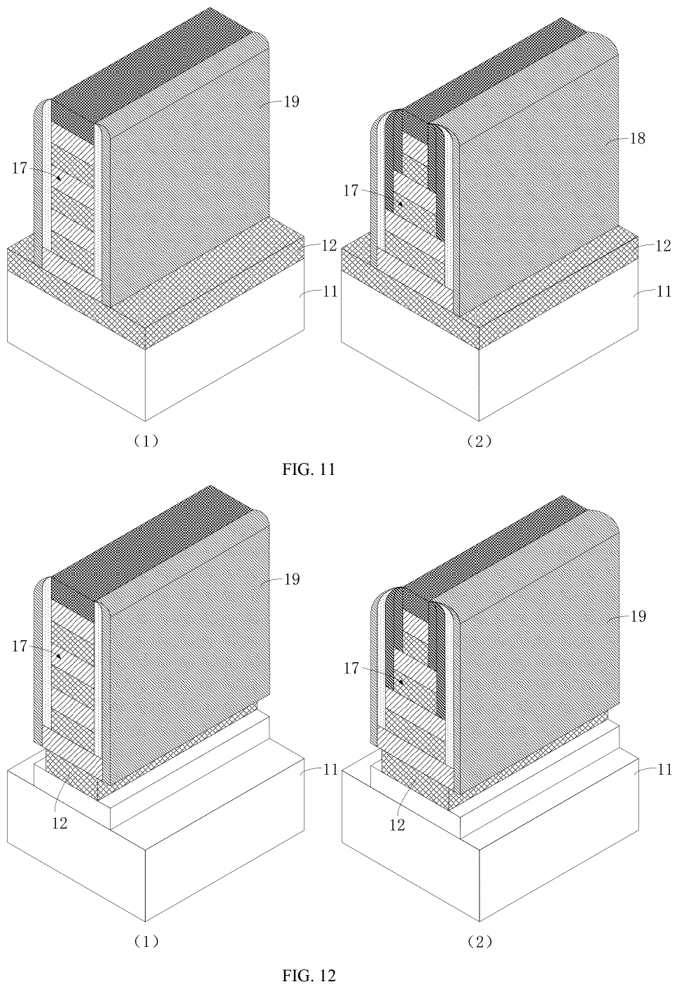

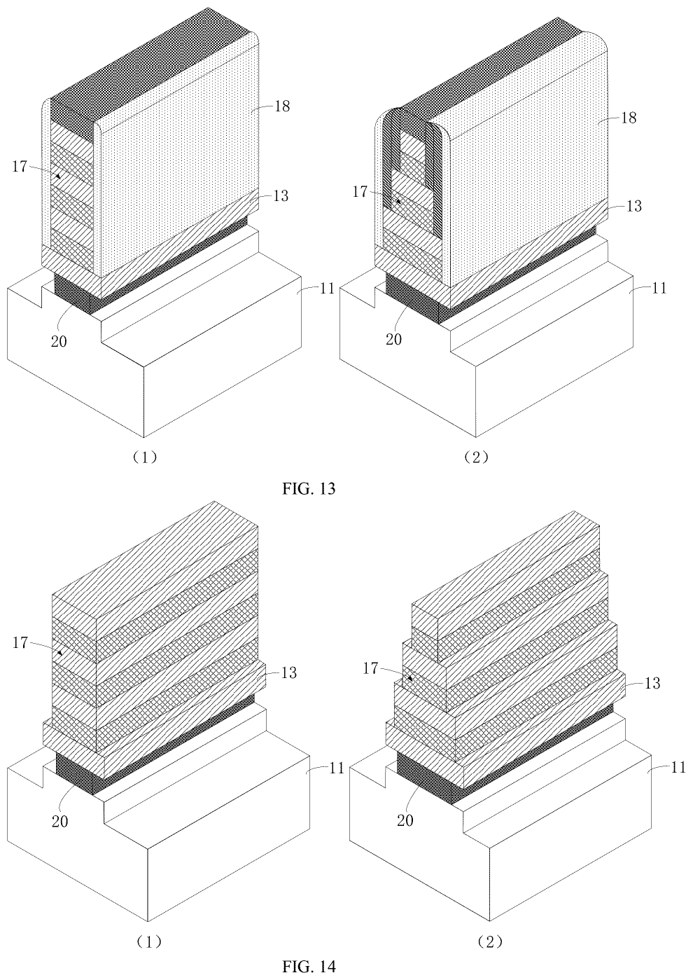

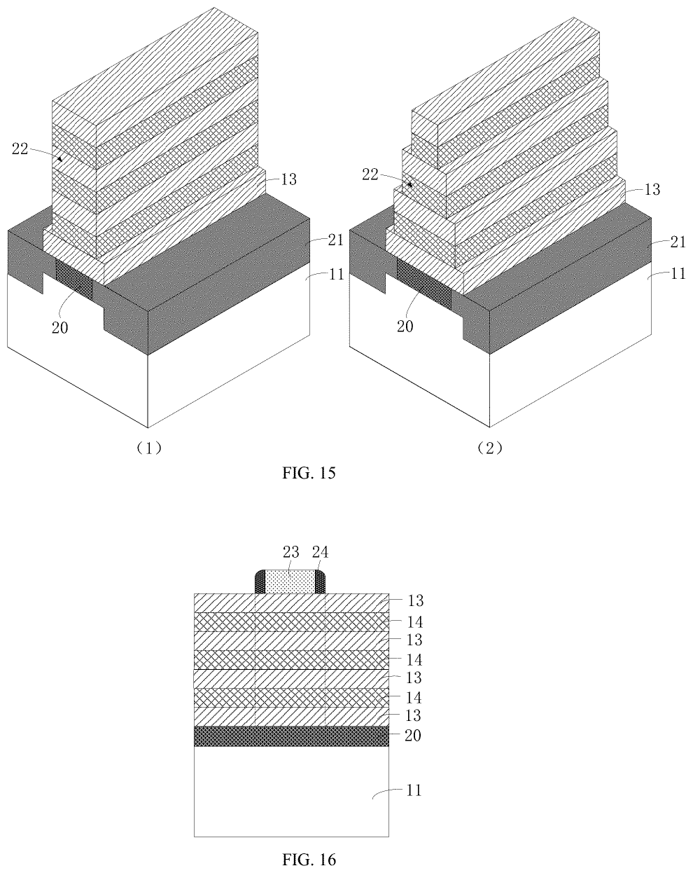

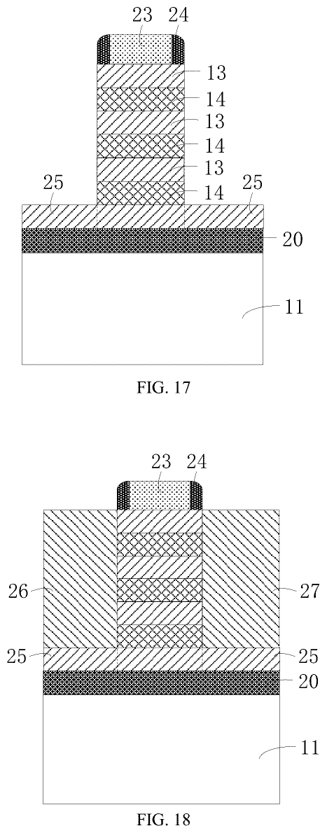

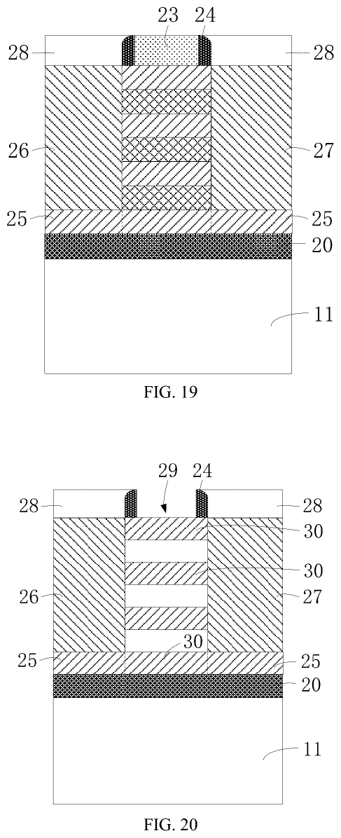

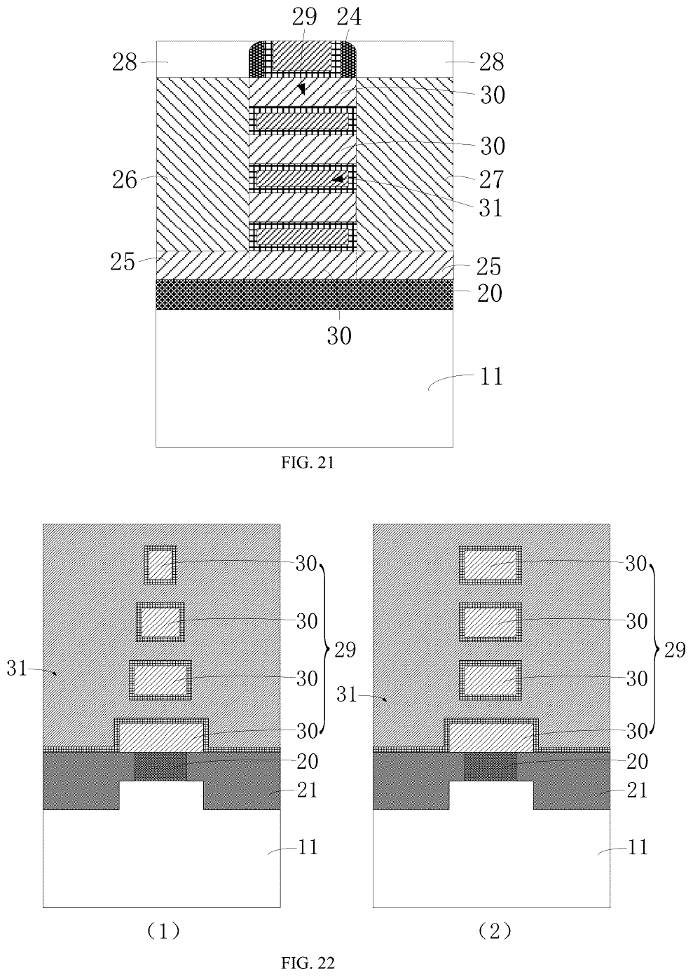

A first method of forming the dielectric structure on the semiconductor base substrate may include the following steps. As shown in FIG. 1, a layer to be oxidized 12, channel layers 13 and sacrificial layers 14 are formed on the semiconductor base substrate 11, where the channel layers 13 and the sacrificial layers 14 are alternately stacked on the layer to be oxidized 12. The bottom channel layer 13 is in contact with the layer to be oxidized 12, and the sacrificial layers 14 are made of the same material as the layer to be oxidized 12. Then, as shown in FIG. 2 and FIG. 7, the other channel layers 13 and the sacrificial layers 14 located above the bottom channel layer 13 are patterned to form a first fin structure 17 on the channel layer 13. Then, as shown in Part (1) of FIG. 8, a first protective layer 18 is formed to cover a periphery of the first fin structure 17. As shown in Part (1) of FIG. 9, at least the bottom channel layer 13 and the layer to be oxidized 12 are etched under a masking action of the first protective layer 18. After that, as shown in Part (1) and Part (2) of FIG. 13, a selective oxidation is performed on a remaining part of the layer to be oxidized, so that the remaining part of the layer to be oxidized is formed into the dielectric structure 20. Then, as shown in Part (1) and Part (2) of FIG. 14, the first protective layer is removed.

During the actual manufacturing process, as shown in FIG. 1, the layer to be oxidized 12, the channel layers 13 and the sacrificial layers 14 may be formed by epitaxy or other processes. The channel layers 13 may be made of a semiconductor material such as silicon. The layer to be oxidized 12 and the sacrificial layers 14 may be made of a semiconductor material that has a particular etching selectivity with respect to the material of the channel layer 13 and that may achieve a selective oxidation with respect to the channel layer 13. For example, the sacrificial layers 14 and the layer to be oxidized 12 may be made of Si₁₋ₓGeₓ, where 0.2≤x≤1. For example, the sacrificial layers 14 and the layer to be oxidized 12 may be made of Si_{0.2}Ge_{0.8}, Si_{0.3}Ge_{0.7}, Si_{0.4}Ge_{0.6} or Si_{0.5}Ge_{0.5}, etc. Then, a mask layer may be formed on the alternately stacked channel layers 13 and sacrificial layers 14 by using processes such as photolithography and etching. Then, as shown in FIG. 2, the other channel layers 13 and the sacrificial layers 14 located above the bottom channel layer 13 may be patterned under the masking action of the same mask layer. In this case, each channel layer 13 included in the first fin structure 17 may have the same width. Accordingly, each nanostructure 30 manufactured based on each channel layer 13 included in the first fin structure 17 may have the same width.

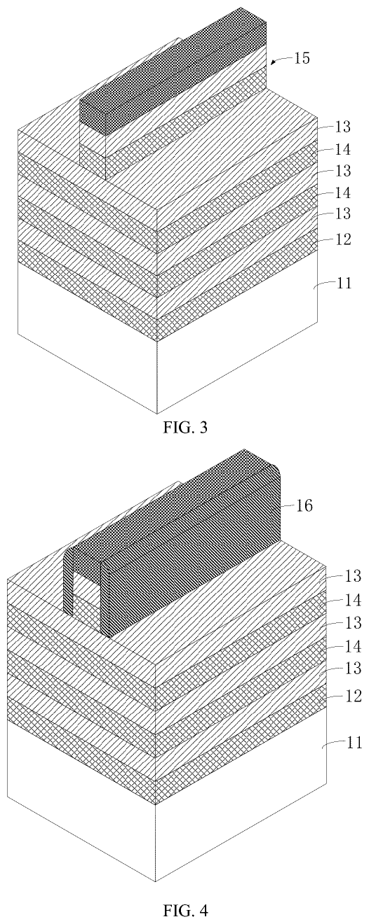

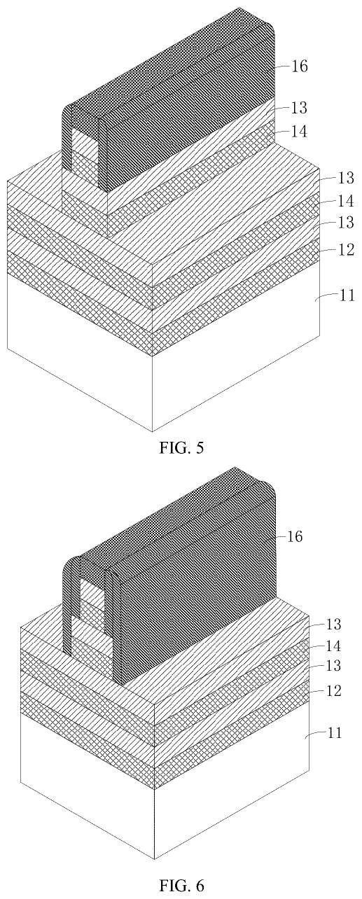

Alternatively, as shown in FIG. 1, if at least three channel layers 13 are formed on the layer to be oxidized 12, patterning the other channel layers 13 and the sacrificial layers 14 located above the bottom channel layer 13 to form the first fin structure on the channel layer 13 may further include the following steps. As shown in FIG. 3, a target layer is patterned using processes such as photolithography and etching to form a third fin structure 15. The above-mentioned target layer is the channel layer 13 and/or the sacrificial layer 14 that have/has not been patterned and that are/is currently located at the top. For example, if four channel layers and three sacrificial layers are formed on the layer to be oxidized, the channel layers and the sacrificial layers are numbered in an ascending order in a direction towards the semiconductor base substrate. Accordingly, when a first operation is performed, the target layer may be a first channel layer, or may be the first channel layer and a first sacrificial layer. When a second operation is performed, if the target layer in the first operation is the first channel layer, the target layer in the second operation may be the first sacrificial layer or may be the first sacrificial layer and a second channel layer; if the target layer in the first operation is the first channel layer and the first sacrificial layer, the target layer in the second operation may be the second channel layer or may be the second channel layer and a second sacrificial layer. Then, as shown in FIG. 4, a third protective layer 16 covering a periphery of the third fin structure may be formed using processes such as deposition and etching. The third protective layer 16 may be made of silicon nitride or the like. In a width direction of the gate stack structure 31, a thickness of the third protective layer 16 may be determined according to a width difference between each two adjacent nanostructures. Then, as shown in FIG. 5 to FIG. 7, the above operations are repeatedly performed until the first fin structure 17 is formed. The number of times that the above operations are repeatedly performed may be determined according to the number of the other channel layers 13 and the sacrificial layers 14 located above the bottom channel layer 13 as well as the object of the target layer in each operation. For example, if four channel layers 13 and three sacrificial layers 14 are formed on the layer to be oxidized 12, and the objects corresponding to the target layer in each operation are the channel layer 13 and the sacrificial layer 14 that have not been patterned and that are currently located at the top, then the operations may be performed three times.

After the first fin structure is formed by at least the above two methods, a first protective layer covering a periphery of the first fin structure may be formed by processes such as deposition and etching. The first protective layer may be made of silicon nitride, etc. In the width direction of the gate stack structure, the thickness of the first protective layer may be determined according to a difference between the width of the bottom nanostructure and the width of the nanostructure located in a second-to-last layer. Then, only the layer to be oxidized and the bottom channel layer are etched by using a dry etching process or a wet etching process, etc. Alternatively, as shown in Part (1) of FIG. 9, only the layer to be oxidized 12, the bottom channel layer 13 and a part of the semiconductor base substrate 11 may be etched. Then, a selective oxidation may be performed on a remaining part of the layer to be oxidized, so that the remaining part of the layer to be oxidized is formed into the dielectric structure 20. Then, as shown in Part (1) and Part (2) of FIG. 14, the first protective layer may be removed by using a dry etching process or a wet etching process, etc.

If a third protective layer is formed when the first fin structure is formed as above, it is further required to remove the third protective layer after removing the first protective layer. Alternatively, the third protective layer may be removed after forming the first fin structure and before forming the first protective layer.

A second method of forming the dielectric structure on the semiconductor base substrate may include the following steps. As shown in FIG. 1, a layer to be oxidized 12, channel layers 13 and sacrificial layers 14 are formed on the semiconductor base substrate 11, where the channel layers 13 and the sacrificial layers 14 are alternately stacked on the layer to be oxidized 12. The bottom channel layer 13 is in contact with the layer to be oxidized 12, and the sacrificial layers 14 are made of the same material as the layer to be oxidized 12. Then, as shown in FIG. 2 and FIG. 7, the other channel layers 13 and the sacrificial layers 14 located above the bottom channel layer 13 are patterned to form a first fin structure 17 on the channel layer 13. Then, as shown in Part (1) and Part (2) of FIG. 8, a first protective layer 18 is formed to cover a periphery of the first fin structure 17. Then, as shown in Part (1) and Part (2) of FIG. 10, the bottom channel layer 13 is etched under the masking action of the first protective layer 18. After that, as shown in Part (1) and Part (2) of FIG. 11, a second protective layer 19 is formed to cover a sidewall of the first protective layer 18 and a sidewall of a remaining part of the bottom channel layer 13. Then, as shown in Part (1) and Part (2) of FIG. 12, at least the layer to be oxidized 12 is etched under the masking action of the first protective layer 18 and the second protective layer 19. After that, a selective oxidation is performed on a remaining part of the layer to be oxidized, so that the remaining part of the layer to be oxidized is formed into the dielectric structure 20. As shown in Part (1) and Part (2) of FIG. 14, the first protective layer and the second protective layer are removed.

During the actual manufacturing process, before etching the bottom channel layer, the manufacturing process corresponding to the second method is the same as the manufacturing process corresponding to the first method, which will not be described in detail here. In the formation of the first protective layer, the second method is different from the first method in that only the bottom channel layer is etched under the masking action of the first protective layer so that the width of the bottom channel layer after patterning is greater than the width of the other channel layers. Then, by using processes such as deposition and etching, as shown in Part (1) and Part (2) of FIG. 11, the second protective layer 19 is formed to cover the sidewall of the first protective layer 18 and the sidewall of the remaining part of the bottom channel layer 13. The second protective layer 19 may be made of silicon nitride or other materials. In the manufacturing method provided in the embodiments of the present disclosure, the thickness of the second protective layer 19 is not limited, as long as the second protective layer 19 may protect the bottom channel layer 13 during the subsequent process of performing a selective oxidation on the layer to be oxidized 12. Then, as shown in Part (1) and Part (2) of FIG. 12, at least the layer to be oxidized 12 may be etched under the masking action of the first protective layer 18 and the second protective layer 19 by using a dry etching process or a wet etching process, etc. After that, a selective oxidation may be performed on a remaining part of the layer to be oxidized, so that the remaining part of the layer to be oxidized is formed into the dielectric structure 20. Then, as shown in Part (1) and Part (2) of FIG. 14, the first protective layer and the second protective layer may be removed by using a dry etching process or a wet etching process, etc.

As shown in Part (1) and Part (2) of FIG. 14, after the selective oxidation is performed, a structure formed on the dielectric structure 20 is a second fin structure 22. The second fin structure 22 includes all channel layers and sacrificial layers that have been patterned. In this case, as shown in Part (1) and Part (2) of FIG. 15, a shallow trench isolation structure 21 may be formed at least on the isolation region of the semiconductor base substrate 11 by using at least deposition and etching. A material and a top height of the shallow trench isolation structure 21 may refer to the above.

Exemplarily, the above-mentioned formation of the active structure on the semiconductor base substrate may include the following steps.

As shown in FIG. 16, a sacrificial gate 23 and a gate spacer 24 spanning across the second fin structure may be formed by processes such as deposition and etching. The gate spacer 24 is located on both sides of the sacrificial gate 23 in the length direction. The sacrificial gate 23 may be made of polysilicon or other materials. The material of the gate spacer 24 may refer to the above.

Then, as shown in FIG. 17, at least a part of the second fin structure is patterned under the masking action of the sacrificial gate 23 and the gate spacer 24 in the direction towards the semiconductor base substrate 11.

Specifically, as shown in FIG. 17, only a part of the second fin structure located above the bottom channel layer 13 may be patterned, under the masking action of the sacrificial gate 23 and the gate spacer 24 in the direction towards the semiconductor base substrate 11. An edge part on both sides of the bottom channel layer 13 in the length direction of the gate stack structure is formed into a semiconductor structure 25.

Alternatively, a part of the second fin structure exposed outside the sacrificial gate and the gate spacer may be completely removed. In this case, both sides of the dielectric structure in the length direction are exposed.

Then, as shown in FIG. 18, a source region 26 and a drain region 27 may be respectively formed on both sides of the second fin structure in the length direction by using epitaxy or other processes.

It should be noted that, as shown in FIG. 17 and FIG. 18, if the above-mentioned semiconductor structure 25 is retained after a part of the second fin structure is patterned, then when forming the source region 26 and the drain region 27, it is possible to not only use at least a remaining part of the channel layer as an epitaxial seed layer, but also use the retained semiconductor structure 25 as an epitaxial seed layer, so as to improve a formation quality of the source region 26 and the drain region 27.

Then, as shown in FIG. 19, an interlayer dielectric layer 28 covering the semiconductor base substrate 11 may be formed by processes such as deposition and planarization. A top of the interlayer dielectric layer 28 is flush with a top of the sacrificial gate 23. A material of the interlayer dielectric layer 28 may refer to the above.

Then, as shown in FIG. 20, the sacrificial gate and the exposed part of each sacrificial layer may be removed by using a dry etching process or a wet etching process, etc., so that an exposed part of each channel layer is formed into a corresponding nanostructure 30, thereby obtaining an active structure.

Then, as shown in FIG. 21 as well as Part (1) and Part (2) of FIG. 22, a gate stack structure 31 may be formed by processes such as atomic layer deposition. The gate stack structure 31 is formed on a surface of the bottom nanostructure 30 not in contact with the dielectric structure 20, and the gate stack structure 31 surrounds a periphery of the other nanostructures 30. A specific structure, a material and other information of the gate stack structure 31 may refer to the above and will not be repeated here.

It should be noted that the above-mentioned active structure and gate stack structure may be formed by a variety of methods. How to form the above-mentioned active structure and gate stack structure is not an essential feature of the present disclosure, and only a brief introduction is given in the specification so that the present disclosure may be easily implemented by those ordinary skilled in the art. Those ordinary skilled in the art may easily imagine other methods to manufacture the above-mentioned active structure and gate stack structure.

The beneficial effects of the second aspect and its various implementations in the embodiments of the present disclosure may be referred to the beneficial effects of the first aspect and its various implementations in the embodiments of the present disclosure, which will not be repeated here.

In the above descriptions, no detailed explanation is given for the technical details such as the patterning and etching of each layer. However, those skilled in the art should understand that various technical means may be used to form layers, regions, etc. of desired shapes. In addition, in order to form the same structure, those skilled in the art may also design a method that is not completely the same as the method described above. Furthermore, although various embodiments have been described above separately, this does not mean that measures in the various embodiments may not be used in combination advantageously.

The embodiments of the present disclosure are described above. However, these embodiments are for illustrative purposes only and are not intended to limit the scope of the present disclosure. The scope of the present disclosure is defined by the appended claims and their equivalents. Without departing from the scope of the present disclosure, those skilled in the art may make various substitutions and modifications, all of which should fall within the scope of the present disclosure.

What is claimed is:

1. A transistor, comprising:
a semiconductor base substrate;
an active structure formed on the semiconductor base substrate, wherein the active structure comprises a source region, a drain region, and a channel region located between the source region and the drain region; the channel region comprises at least two nanostructures stacked in a thickness direction of the semiconductor base substrate; and in the channel region, a bottom nanostructure of the at least two nanostructures has a greater width than others of the at least two nanostructures;
a dielectric structure formed between the semiconductor base substrate and the active structure, wherein the dielectric structure is in contact with the bottom nanostructure; and
a gate stack structure, wherein the gate stack structure is formed on a surface of the bottom nanostructure not in contact with the dielectric structure, and the gate stack structure surrounds a periphery of the others of the at least two nanostructures.

2. The transistor according to claim 1, wherein in the channel region, the others of the at least two nanostructures other than the bottom nanostructure have a same width; or
wherein in a direction towards the semiconductor base substrate, widths of different nanostructures comprised in the channel region gradually increase.

3. The transistor according to claim 2, wherein central axes of the different nanostructures comprised in the channel region coincide with each other.

4. The transistor according to claim 1, wherein a width of the dielectric structure is less than the width of the bottom nanostructure.

5. The transistor according to claim 1, wherein the transistor further comprises a semiconductor structure integrally formed with the bottom nanostructure, and the semiconductor structure is located between the source region and the dielectric structure as well as between the drain region and the dielectric structure.

6. A method of manufacturing a transistor, comprising:
providing a semiconductor base substrate;
forming a dielectric structure and an active structure on the semiconductor base substrate, wherein the active structure comprises a source region, a drain region, and a channel region located between the source region and the drain region; the channel region comprises at least two nanostructures stacked in a thickness direction of the semiconductor base substrate; in the channel region, a bottom nanostructure of the at least two nanostructures has a greater width than others of the at least two nanostructures; the dielectric structure is formed between the semiconductor base substrate and the active structure and is in contact with the bottom nanostructure; and
forming a gate stack structure, wherein the gate stack structure is formed on a surface of the bottom nanostructure not in contact with the dielectric structure, and the gate stack structure surrounds a periphery of the others of the at least two nanostructures.

7. The method of manufacturing the transistor according to claim 6, wherein the forming a dielectric structure on the semiconductor base substrate comprises:
forming a layer to be oxidized, channel layers and sacrificial layers on the semiconductor base substrate, wherein the channel layers and the sacrificial layers are alternately stacked on the layer to be oxidized; a bottom channel layer of the channel layers is in contact with the layer to be oxidized; and the sacrificial layers are made of a same material as the layer to be oxidized;
patterning the sacrificial layers and others of the channel layers located above the bottom channel layer, so as to form a first fin structure on the channel layer;
forming a first protective layer to cover a periphery of the first fin structure;
etching, under a masking action of the first protective layer, at least the bottom channel layer and the layer to be oxidized;
performing a selective oxidation on a remaining part of the layer to be oxidized, so that the remaining part of the layer to be oxidized is formed into the dielectric structure; and
removing the first protective layer.

8. The method of manufacturing the transistor according to claim 6, wherein the forming a dielectric structure on the semiconductor base substrate comprises:
forming a layer to be oxidized, channel layers and sacrificial layers on the semiconductor base substrate, wherein the channel layers and the sacrificial layers are alternately stacked on the layer to be oxidized; a bottom channel layer of the channel layers is in contact with the layer to be oxidized; and the sacrificial layers are made of a same material as the layer to be oxidized;
patterning the sacrificial layers and others of the channel layers located above the bottom channel layer, so as to form a first fin structure on the channel layer;
forming a first protective layer to cover a periphery of the first fin structure;
etching the bottom channel layer under a masking action of the first protective layer;
forming a second protective layer to cover a sidewall of the first protective layer and a sidewall of a remaining part of the bottom channel layer;
etching at least the layer to be oxidized under a masking action of the first protective layer and the second protective layer;
performing a selective oxidation on a remaining part of the layer to be oxidized, so that the remaining part of the layer to be oxidized is formed into the dielectric structure; and
removing the first protective layer and the second protective layer.

9. The method of manufacturing the transistor according to claim 7, wherein the sacrificial layers and the layer to be oxidized are made of Si₁₋ₓGeₓ, and 0.2≤x≤1; and/or
wherein the channel layers are made of Si.

10. The method of manufacturing the transistor according to claim 8, wherein the sacrificial layers and the layer to be oxidized are made of Si₁₋ₓGeₓ, and 0.2≤x≤1; and/or
wherein the channel layers are made of Si.

11. The method of manufacturing the transistor according to claim 7, wherein a structure formed on the dielectric structure after the selective oxidation is performed is a second fin structure; and
wherein the forming an active structure on the semiconductor base substrate comprises:
forming a sacrificial gate and a gate spacer spanning across the second fin structure, wherein the gate spacer is located on both sides of the sacrificial gate in a length direction;
patterning at least a part of the second fin structure in a direction towards the semiconductor base substrate under a masking action of the sacrificial gate and the gate spacer;
forming the source region and the drain region respectively on both sides of the second fin structure in the length direction; and
removing the sacrificial gate and removing an exposed part of each sacrificial layer, so that an exposed part of each channel layer is formed into a corresponding nanostructure.

12. The method of manufacturing the transistor according to claim 8, wherein a structure formed on the dielectric structure after the selective oxidation is performed is a second fin structure; and
wherein the forming an active structure on the semiconductor base substrate comprises:
forming a sacrificial gate and a gate spacer spanning across the second fin structure, wherein the gate spacer is located on both sides of the sacrificial gate in a length direction;
patterning at least a part of the second fin structure in a direction towards the semiconductor base substrate under a masking action of the sacrificial gate and the gate spacer;
forming the source region and the drain region respectively on both sides of the second fin structure in the length direction; and
removing the sacrificial gate and removing an exposed part of each sacrificial layer, so that an exposed part of each channel layer is formed into a corresponding nanostructure.

13. The method of manufacturing the transistor according to claim 11, wherein the patterning at least a part of the second fin structure in a direction towards the semiconductor base substrate under a masking action of the sacrificial gate and the gate spacer comprises:
patterning, under the masking action of the sacrificial gate and the gate spacer, a part of the second fin structure located on the bottom channel layer in the direction towards the semiconductor base substrate; wherein an edge part on both sides of the bottom channel layer in a length direction of the gate stack structure is formed into a semiconductor structure.

14. The method of manufacturing the transistor according to claim 7, wherein the patterning the sacrificial layers and others of the channel layers located above the bottom channel layer, so as to form a first fin structure on the channel layer comprises:
patterning, under a masking action of a same mask layer, the sacrificial layers and the others of the channel layers located above the bottom channel layer.

15. The method of manufacturing the transistor according to claim 8, wherein the patterning the sacrificial layers and others of the channel layers located above the bottom channel layer, so as to form a first fin structure on the channel layer comprises:
patterning, under a masking action of a same mask layer, the sacrificial layers and the others of the channel layers located above the bottom channel layer.

16. The method of manufacturing the transistor according to claim 7, wherein at least three channel layers are formed on the layer to be oxidized; and
wherein the patterning the sacrificial layers and others of the channel layers located above the bottom channel layer, so as to form a first fin structure on the channel layer comprises:
patterning a target layer to form a third fin structure, wherein the target layer is the channel layer and/or the sacrificial layer that have/has not been patterned and are/is currently at a top;
forming a third protective layer to cover a periphery of the third fin structure; and
repeatedly performing the patterning a target layer and the forming a third protective layer until the first fin structure is formed.

17. The method of manufacturing the transistor according to claim 8, wherein at least three channel layers are formed on the layer to be oxidized; and
wherein the patterning the sacrificial layers and others of the channel layers located above the bottom channel layer, so as to form a first fin structure on the channel layer comprises:
patterning a target layer to form a third fin structure, wherein the target layer is the channel layer and/or the sacrificial layer that have/has not been patterned and are/is currently at a top;
forming a third protective layer to cover a periphery of the third fin structure; and
repeatedly performing the patterning a target layer and the forming a third protective layer until the first fin structure is formed.
